(19) United States
(12) Patent Application Publication
(10) Pub. No.: US 2015/0303652 A1
(43) Pub. Date: Oct. 22, 2015

(54) Temperature Controllable High Bit Rate Laser Diode

(71) Applicant: LIGHTRON FIBER-OPTIC DEVICES INC, Daejeon (KR)

(72) Inventors: Jin Soo Choi, Daejeon (KR); Yoon Koo Kwon, Cheongju-si (KR); Se Yong Song, Daejeon (KR); Dong Hyun Lee, Daejeon (KR)

(21) Appl. No.: 14/646,192

(22) PCT Filed: Nov. 20, 2013
(86) PCT No.: PCT/KR2013/010579

§ 371 Date: May 20, 2015

(30) Foreign Application Priority Data
Nov. 30, 2012 (KR) 10-2012-0137462

(51) Int. Cl. H01S 5/068; H01S 5/022; H01S 5/024

(52) U.S. Cl. CPC H01S 5/06804; H01S 5/02415; H01S 5/02252

(57) ABSTRACT

Provided is a temperature controllable high bit rate laser diode. The temperature controllable high bit rate laser diode includes: a stem including a plurality of electrodes protruding in a form of signal pins and arranged in two rows; a thermoelectric cooler provided on the stem and controlling a temperature of the temperature controllable high bit rate laser diode; and a sub mount positioned over the thermoelectric cooler and supporting a laser diode chip, a reflection mirror, and a monitor photodiode measuring output light intensity of the temperature controllable high bit rate laser diode.

### TECHNICAL FIELD

The present invention relates to a temperature controllable high bit rate laser diode, and more particularly, to a temperature controllable high bit rate laser diode capable of maintaining a wavelength change depending on an external temperature change to be small by having a thermoelectric element embedded therein to decrease a temperature change of the laser diode itself.

### BACKGROUND ART

Currently, optical communication has been widely used as a method of transmitting and receiving a large amount of information. The optical communication has circulated massive information directly to a home through optical repeating in a scheme such as an FTTH (Fiber To The Home) scheme, an FTTP (Fiber To The Pole) scheme, or the like, as well as information communication between nations.

In the optical communication for circulating the massive information as described above, a light emitting device, which is a device generating light used for the optical communication, an optical fiber, which is a medium transferring an optical signal, and a light receiving device converting the transferred optical signal into an electrical signal are required as requisite components. Among them, a laser diode using a semiconductor device manufacturing method is used as the light emitting device generating the light used for the optical communication. The laser diode is a device converting an electrical signal into an optical signal.

The laser diode has a wavelength changed depending on a temperature change of an external environment under which it is to be used. Generally, when an operation temperature of the laser diode rises, an internal loss of the laser diode is increased and an internal gain thereof is decreased, which causes characteristics of a current-output optical power of the laser diode to be deteriorated.

For example, in the case of a distributed feedback laser diode, when a temperature rise of 1° C. causes a wavelength increase of about 0.1 nm, and when a temperatures falls, a wavelength is decreased.

Currently, in an environment under which an optical communication system is installed, it is internationally required that the optical communication system is stably operated at a temperature of −40 to 85° C. However, when the laser diode is used in this temperature range, a wavelength change of the laser diode based on a room temperature of 25° C. is about −6.5 nm to +6 nm.

In addition, a Febry-Perot type laser diode corresponding to a general structure of a semiconductor laser diode has an excellent photoelectric converting efficiency under an operating environment of a low temperature (40 to 50° C.), but is not operated well in an operating environment of a high temperature (50° C. or more), as described above.

Therefore, in order to maintain a wavelength change depending on an external temperature change to be small, a design for decreasing a temperature change of the laser diode itself has been demanded.

Korean Patent Laid-Open Publication No. 2009-0017246 (hereinafter, referred to as Related Art Document 1) entitled “Laser Diode Package with Thermal Dissipation Member” has disclosed a laser diode package with a thermal dissipation member capable of dissipating heat generated from a laser diode chip and an embedded thermoelectric element by attaching a metal bar for radiating heat to a bottom surface of the laser diode package and attaching a connecting member having flexibility to the metal bar to effectively establish a heat transfer path in a narrow housing such as a small form factor (SFF), a small form factor pluggable (SFP), or the like.

However, Related Art Document 1 fails to disclose that a bandwidth is limited at the time of performing transmission at a high bit rate at all.

### RELATED ART DOCUMENT

### Patent Document

Korean Patent Laid-Open Publication No. 10-2009-0017246 (published on Feb. 18, 2009)

### DISCLOSURE OF INVENTION

### Technical Problem

An object of the present invention is to provide a temperature controllable high bit rate laser diode capable of maintaining a wavelength change depending on an external temperature change to be small by having a thermoelectric element embedded therein to decrease a temperature change of the laser diode itself.

### Solution to Problem

In one general aspect, a temperature controllable high bit rate laser diode may include: a stem 100 including a plurality of electrodes protruding in a form of signal pins and arranged in two rows; a thermoelectric cooler (TEC) 200 provided on the stem 100 and controlling a temperature of the temperature controllable high bit rate laser diode; and a sub mount 300 positioned over the thermoelectric cooler 200 and supporting a laser diode chip 310, a reflection mirror 320, and a monitor photodiode 330 measuring output light intensity of the temperature controllable high bit rate laser diode.

The signal pins may be separation type signal pins glass-sealed from the stem 100 to thereby be electrically insulated from the stem.

The temperature controllable high bit rate laser diode may further include a radio frequency (RF) impedance matching resistor 400 connected to the separation type signal pins depending on a bit rate of the temperature controllable high bit rate laser diode and detachably provided on the sub mount 300.

The stem 100 may further include an integrated ground pin 110 positioned therebeneath and removing RF noise generated from the stem 100 and the signal pins.

The sub mount 300 may further include a thermistor 340 positioned to be close to the laser diode chip 310 and minimizing a measuring deviation of an internal temperature of the temperature controllable high bit rate laser diode.

The RF impedance matching resistor 400 may be provided on the separation type signal pin.

The RF impedance matching resistor 400 may be provided on the thermoelectric cooler 200.

### Advantageous Effects of Invention

The temperature controllable high bit rate laser diode according to the exemplary embodiment of the present invention having the configuration as described above has a thermoelectric element embedded therein to decrease a temperature change of the laser diode itself, thereby making it possible to maintain a wavelength change depending on an external temperature change to be small.

In addition, the RF impedance matching resistor may be attached and detached depending on a bit rate, and a small RF impedance matching resistor or a double-type RF impedance matching resistor is configured in order to prevent heat generated from the RF impedance matching resistor from having a direct effect on a temperature change of the laser diode chip, thereby making it possible to maintain a wavelength change depending an internal temperature change as well as the external temperature change to be small.

### BRIEF DESCRIPTION OF DRAWINGS

The above and other objects, features and advantages of the present invention will become apparent from the following description of preferred embodiments given in conjunction with the accompanying drawings, in which:

FIG. 1 is a configuration diagram of a temperature controllable high bit rate laser diode according to an exemplary embodiment of the present invention;

FIG. 2 is a perspective view of the temperature controllable high bit rate laser diode according to the exemplary embodiment of the present invention;

FIG. 3 is a front view of the temperature controllable high bit rate laser diode according to the exemplary embodiment of the present invention;

FIG. 4 is another configuration diagram of the temperature controllable high bit rate laser diode according to the exemplary embodiment of the present invention;

FIG. 5 is a perspective view showing a separation type signal pin of the temperature controllable high bit rate laser diode according to the exemplary embodiment of the present invention;

FIG. 6 is a bottom view of the temperature controllable high bit rate laser diode according to the exemplary embodiment of the present invention;

FIG. 7 is a perspective view showing an integrated ground pin of the temperature controllable high bit rate laser diode according to the exemplary embodiment of the present invention;

FIG. 8 is a view showing an example of a radio frequency (RF) impedance matching resistor of the temperature controllable high bit rate laser diode according to the exemplary embodiment of the present invention; and

FIG. 9 is a view showing another example of an RF impedance matching resistor of the temperature controllable high bit rate laser diode according to the exemplary embodiment of the present invention.

### BEST MODE FOR CARRYING OUT THE INVENTION

Hereinafter, a temperature controllable high bit rate laser diode according to an exemplary embodiment of the present invention will be described in detail with reference to the accompanying drawings. The drawings to be provided below are provided by way of example so that the idea of the present invention can be sufficiently transferred to those skilled in the art to which the present invention pertains. Therefore, the present invention is not be limited to the drawings provided below but may be modified in many different forms. In addition, like reference numerals denote like elements throughout the specification.

Technical terms and scientific terms used in the present specification have the general meaning understood by those skilled in the art to which the present invention pertains unless otherwise defined, and a description for the known function and configuration obscuring the present invention will be omitted in the following description and the accompanying drawings.

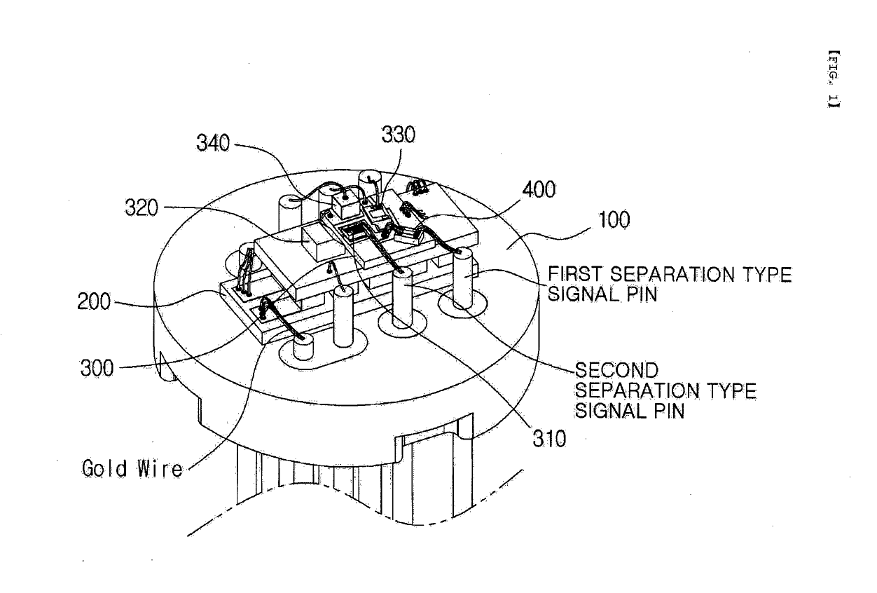

A temperature controllable high bit rate laser diode according to an exemplary embodiment of the present invention may be configured to include a stem 100, a thermoelectric cooler (TEC) 200, a sub mount 300 supporting a laser diode chip 310, a reflection mirror 320, a monitor photodiode 330, and a radio frequency (RF) impedance matching resistor 400, as shown in FIGS. 1 to 4.

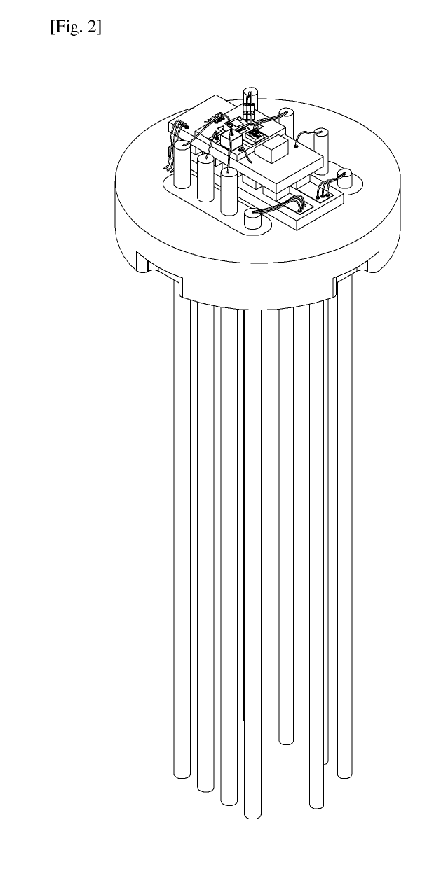

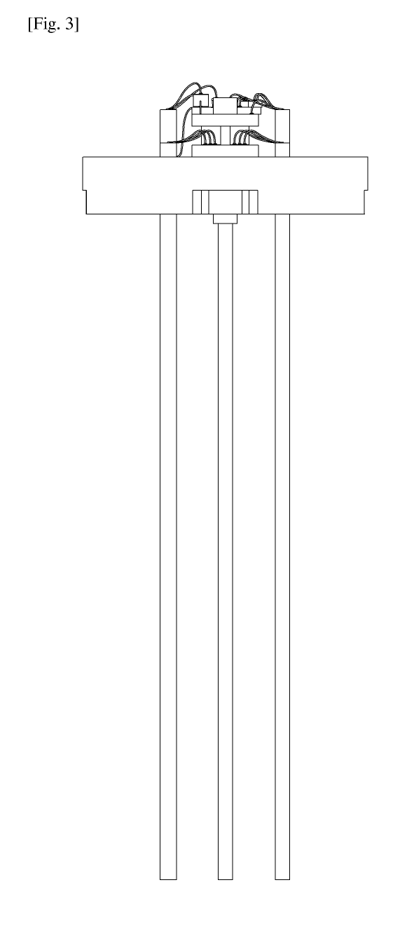

FIGS. 2 and 3 are views variously showing the temperature controllable high bit rate laser diode including the stem 100, the thermoelectric cooler 200, the sub mount 300, and the RF impedance matching resistor 400 as described above.

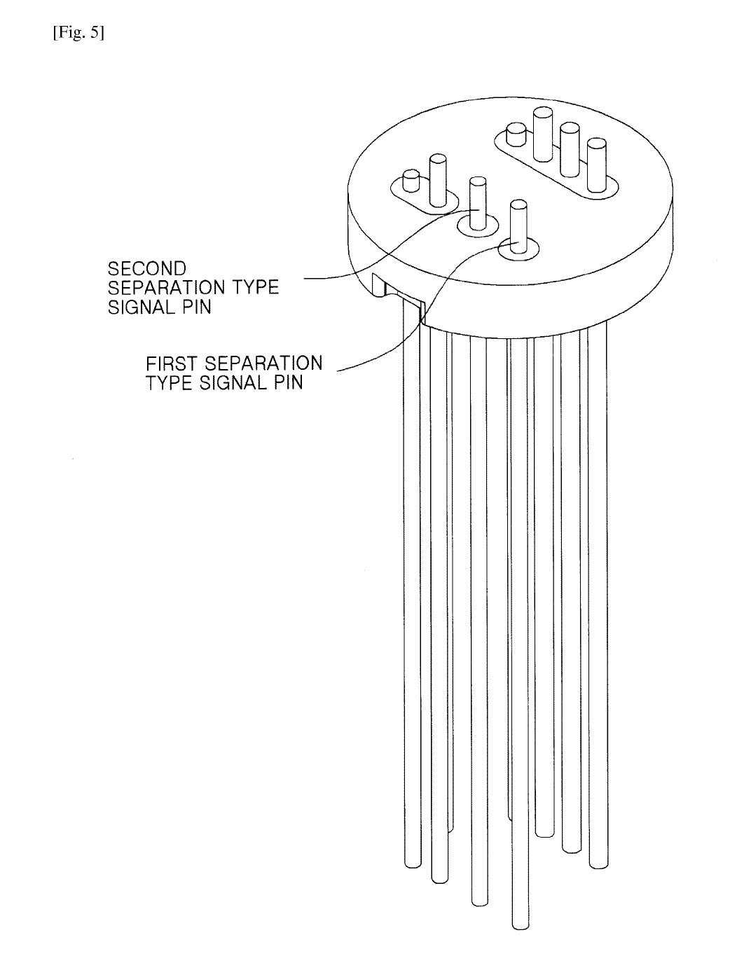

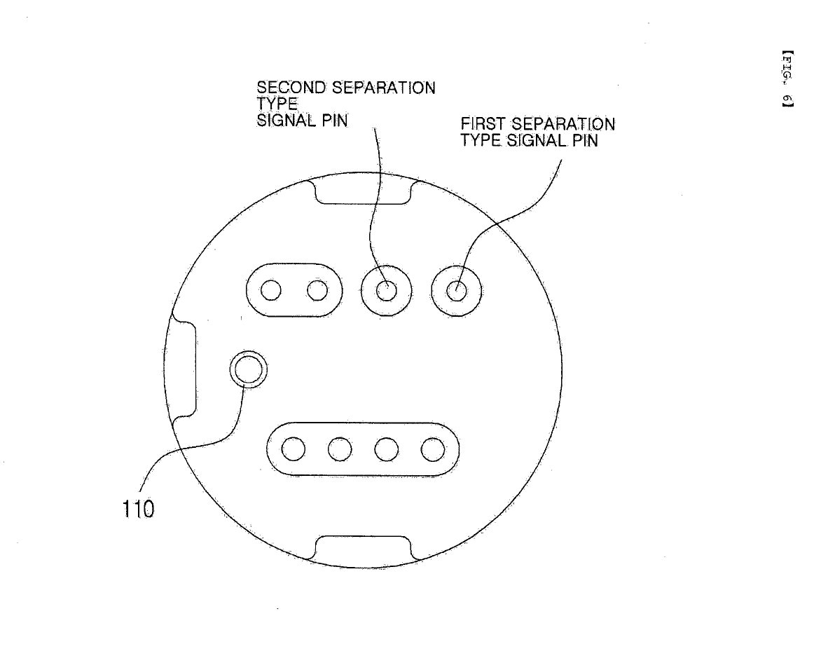

In detail, the stem 100 includes a plurality of electrodes protruding in a form of signal pins, as shown in FIGS. 5 and 6, wherein the signal pins are arranged in two rows. Here, a plurality of signal pins may have a predetermined height and be separation type signal pins glass-sealed from the stem 100 to thereby be electrically insulated from the stem 100.

Here, the separation type signal pins may include a first separation type signal pin and a second separation type signal pin and be glass-sealed from the stem 100, respectively, to thereby be configured in a form of a single pin. Through the above-mentioned configuration, the RF impedance matching resistor 400 may be easily connected to or contact the separation type signal pin.

The separation signal pins may be formed of the respective LD cathode terminals and LD anode terminals depending to a configured internal circuit.

In addition, the predetermined height means a height obtained by adding a height of the thermoelectric cooler 200 and the sub mount 300 provided on the stem 100 and a height of the laser diode chip 310 provided on the sub mount 300 to each other and is generally 1 to 1.5 mm. Here, the predetermined height is only an example of the present invention.

The separation type signal pins are used in a direct modulation lasers (DML) scheme of directly modulating an output signal of the laser diode. This scheme is called a single-ended driving scheme of using only one output. In the case in which the separation type signal pins are used in the DML scheme as described above, impedance matching by a value of 25 ohm (±10%) may be applied to each of the separation type signal pins. This is only an example of the present invention.

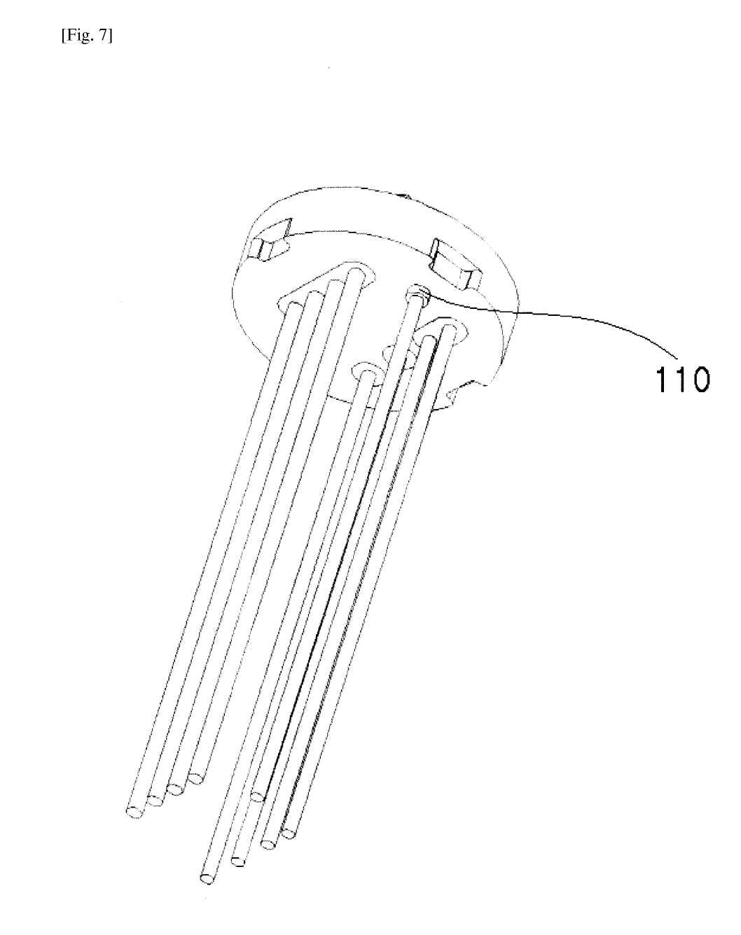

The stem 100 may further include an integrated ground pin 110 removing RF noise generated from the stem 100 and the plurality of signal pins, as shown in FIGS. 6 and 7.

Here, the integrated ground pin 110 may be provided beneath the stem 100 and induce the RF noise thereto to remove the RF noise. As a result, the stem 100 itself may serve as a ground (GND).

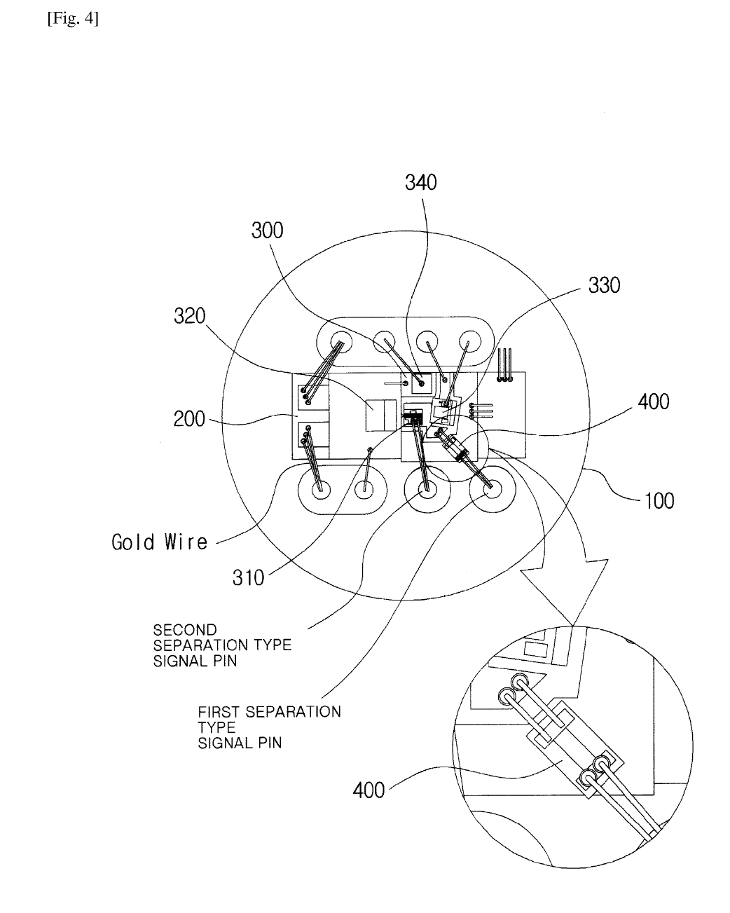

The thermoelectric cooler 200 may be provided on the stem 100 as shown in FIGS. 1 and 4 to control a temperature of the temperature controllable high bit rate laser diode. Since the temperature controllable high bit rate laser diode according to the exemplary embodiment of the present invention has the thermoelectric cooler 200 embedded therein, a temperature change of the temperature controllable high bit rate laser diode itself may be decreased. Therefore, a wavelength change may be maintained to be small.

The thermoelectric cooler 200 may lower an operation temperature of the laser diode chip using a Peltier effect and be usually used to control a temperature.

The thermoelectric cooler 200, which is a temperature control device manufactured by a PN junction, controls a temperature using heat absorption and heat generation generated by the Peltier effect generated at a junction part of the device when a current is applied to P-type and N-type thermoelectric semiconductors. Therefore, in the case in which a temperature is to be lowered, a surface of which the temperature is to be lowered becomes cold by the heat absorption. Thus, a surface opposite to the surface generates heat corresponding to the lowered temperature by the heat generation. Through the above-mentioned operation, the thermoelectric cooler 200 may perform the temperature control.

The sub mount 300 may be provided over the thermoelectric cooler 200 and support the laser diode chip 310, the reflection mirror 320, and the monitor photodiode 330, as shown in FIGS. 1 and 4.

In detail, laser light generated by the laser diode chip 310 may be reflected on a surface of the reflection mirror 320, such that an angle of light emitted to the outside of the stem 100 may be determined. Usually, the reflection mirror 320 polished at an angle of 45 degrees is used to emit the laser light generated by the laser diode chip 310 perpendicularly to a bottom surface of the stem 100.

Here, an angle at which the reflection mirror 320 is polished may be changed in the range of 41 to 49 degrees depending on an angle (0 to 8 degrees) at which a ferrule in which an optical fiber having laser light coupled thereto is embedded is polished.

The monitor photodiode 330 is to monitor an operation of the temperature controllable high bit rate laser diode according to the exemplary embodiment of the present invention. In other words, the monitor photodiode 330 is a monitor light receiving device for measuring output light intensity of the laser diode chip 310. A light receiving part of the monitor photodiode 330 may be formed at a side of the monitor photodiode 330. In order for the monitor photodiode 330 to effectively measure the output light intensity of the laser diode chip 310, a distance between a light emitting part of the laser diode chip 310 and the light receiving part of the monitor photodiode 330 needs to be controlled. This control is performed by moving a position of the monitor photo diode 330.

Further, the sub mount 300 may further include and support a thermistor 340. Therefore, the thermistor 340 may be positioned to be close to the laser diode chip 310. Here, the thermistor 340 means a temperature sensing device for measuring an internal temperature of the temperature controllable high bit rate laser diode according to the exemplary embodiment of the present invention and is positioned to be close to the laser diode chip 310, thereby making it possible to minimize a measuring deviation of the internal temperature of the temperature controllable high bit rate laser diode. In other words, in monitoring the internal temperature of the temperature controllable high bit rate laser diode by the thermistor 340, the sub mount 300 disposes the thermistor 340 to be close to the laser diode chip 310, thereby making it possible to minimize a monitoring deviation of the internal temperature.

The RF impedance matching resistor 400 may be detachably connected to the separation type signal pins depending on a bit rate of the temperature controllable high bit rate laser diode and be provided on the sub mount 300, as shown in FIGS. 1 and 4.

In other words, in the case in which the temperature controllable high bit rate laser diode according to the exemplary embodiment of the present invention transmits optical signals at a high bit rate (of 25 Gbps), the RF impedance matching resistor 400 may be used, and in the case in which the temperature controllable high bit rate laser diode according to the exemplary embodiment of the present invention transmits optical signals at a low bit rate, since importance of impedance matching is decreased, the RF impedance matching resistor 400 may be removed. Particularly, in the case in which the temperature controllable high bit rate laser diode according to the exemplary embodiment of the present invention transmits optical signals at a low bit rate, the RF impedance matching resistor 400 which is unnecessary is removed, thereby making it possible to decrease a process cost.

Here, although the case in which the RF impedance matching resistor 400 is connected only to the first separation type signal pins has been shown in FIGS. 1 and 4, this is only an example of the present. That is, the high bit rate laser diode and the RF impedance matching resistor 400 are also connected to each other through the second separation type signal pins, such that the RF impedance matching resistor 400 may be provided on the sub mount 300.

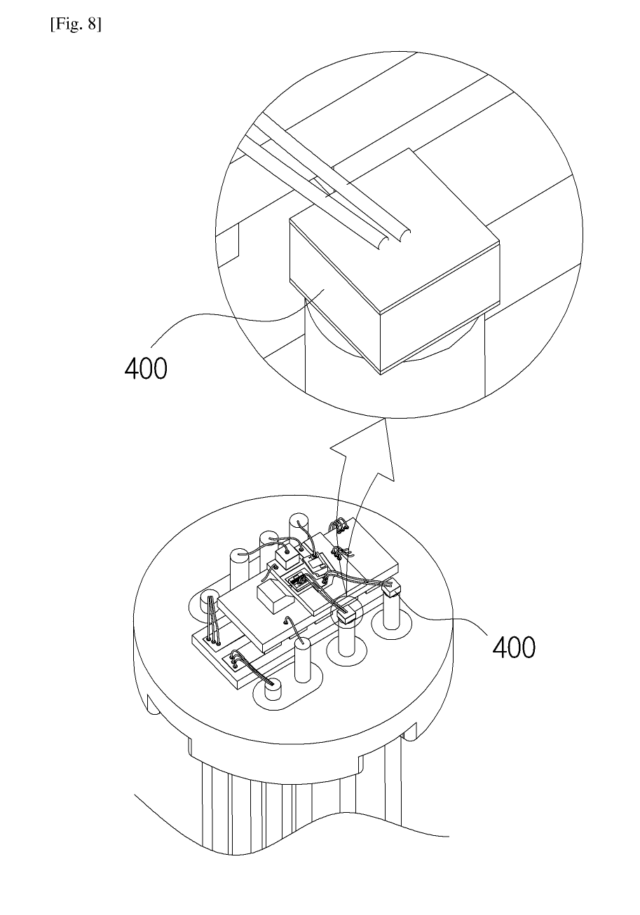

Further, in order to prevent a temperature change of the laser diode chip 310 due to the heat generated from the RF impedance matching resistor 400 itself, the RF impedance matching resistor 400 may be formed at a small size and be directly attached on the separation type signal pin, as shown in FIG. 8.

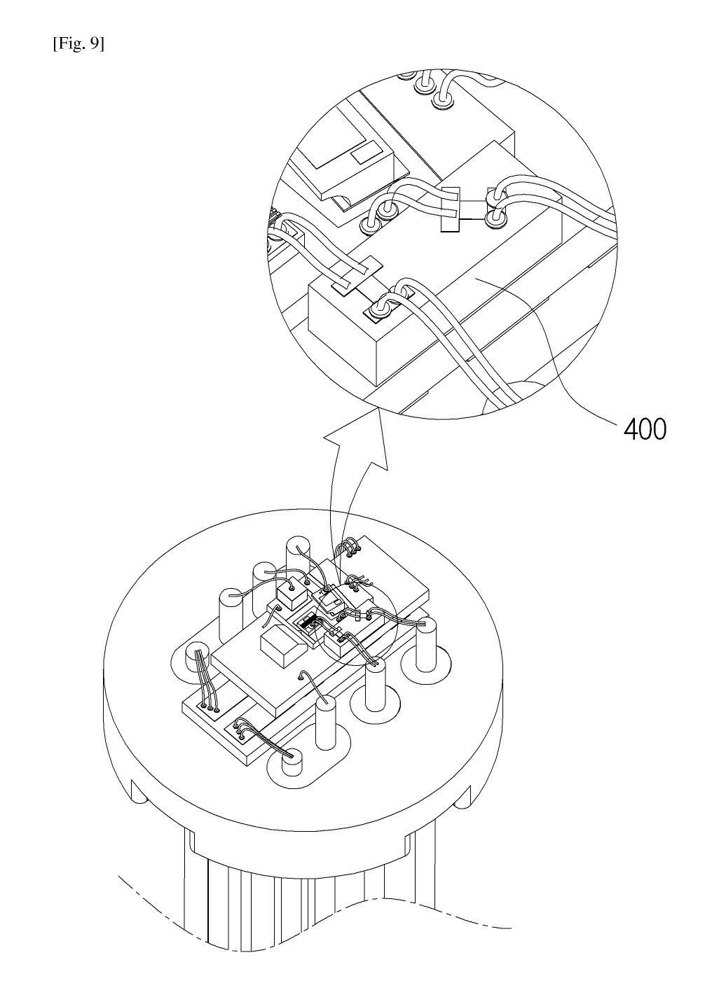

Further, in order to prevent the temperature change of the laser diode chip 310 due to the heat generated from the RF impedance matching resistor 400 itself as described above, the RF impedance matching resistor 400 may also be provided on the thermo-electric cooler 200, as shown in FIG. 9. In this case, since the RF impedance matching resistor 400 is provided on the thermoelectric cooler 200, the sub mount 300 may be minimized, and a double-type RF impedance matching resistor 400 may also be configured by mounting two resistors on a single mount in a double type.

In other words, the temperature controllable high bit rate laser diode according to the exemplary embodiment of the present invention may be configured to include the stem 100, the thermoelectric cooler 200, and the sub mount 300. Here, in the case in which the temperature controllable high bit rate laser diode according to the exemplary embodiment of the present invention performs transmission at a high bit rate, it may further include the RF impedance matching resistor 400 to smoothly perform optical communication.

The plurality of signal pins of the stem 100 are formed of the separation type signal pins in a glass sealing form in which they are electrically insulated, thereby making it possible to easily connect the RF impedance matching resistor 400 and the stem 100 to each other. Further, the laser diode chip 310 and the thermistor 340 provided on the sub mount 300 are positioned to be closed to each other, thereby making it possible to minimize a monitoring deviation of a temperature of the laser diode chip 310.

Further, in order to prevent the temperature change of the laser diode chip 310 due to the heat generated from the RF impedance matching resistor 400 itself, the RF impedance matching resistor 400 may be formed at a small size and be directly attached on the separation type signal pin or the RF impedance matching resistors 400 may be formed doubly so that the two resistors are mounted on the single mount and be provided on the thermoelectric cooler 200, thereby minimizing the sub mount 300.

Hereinabove, although the present invention is described by specific matters such as concrete components, and the like, exemplary embodiments, and drawings, they are provided only for assisting in the entire understanding of the present invention. Therefore, the present invention is not limited to the exemplary embodiments. Various modifications and changes may be made by those skilled in the art to which the present invention pertains from this description.

Therefore, the spirit of the present invention should not be limited to the above-described exemplary embodiments, and the following claims as well as all modified equally or equivalently to the claims are intended to fall within the scope and spirit of the invention.

### DETAILED DESCRIPTION OF MAIN ELEMENTS

100: Stem
110: Integrated ground pin
200: Thermoelectric cooler
300: Sub mount
310: Laser diode chip
320: Reflection mirror
330: Monitor photodiode
340: Thermistor
400: RF impedance matching resistor

1. A temperature controllable hige bit rate laser diode comprising:
a stem including a plurality of electrodes protruding in a form of signal pins and arranged in two rows;
a thermoelectric cooler provided on the stem and controlling a temperature of the temperature controllable high bit rate laser diode; and
a sub mount positioned over the thermoelectric cooler and supporting a laser diode chip, a reflection mirror, and a monitor photodiode measuring output light intensity of the temperature controllable high bit rate laser diode.

2. The temperature controllable high bit rate laser diode of claim 1, wherein the signal pins are separation type signal pins glass-sealed from the stem to thereby be electrically insulated from the stern.

3. The temperature controllable high bit rate laser diode of claim 2, further comprising a radio frequency (RF) impedance matching resistor connected to the separation type signal pins depending on a bit rate of the temperature controllable high bit rate laser diode and detachably provided on the sub mount.

4. The temperature controllable high bit rate laser diode of claim 1, wherein the stem further includes an integrated ground pin positioned therebeneath and removing RF noise generated from the stem and the signal pins.

5. The temperature controllable high bit rate laser diode of claim 1, wherein the sub mount further includes a thermistor positioned to be close to the laser diode chip and minimizing a measuring deviation of an internal temperature of the temperature controllable high bit rate laser diode.

6. The temperature controllable high bit rate laser diode of claim 3, wherein the RF impedance matching resistor is provided on the separation type signal pin.

7. The temperature controllable high bit rate laser diode of claim 3, wherein the RF impedance matching resistor is provided on the thermoelectric cooler.
